(19) United States
(12) Patent Application Publication
(10) Pub. No.: US 2026/0106583 A1
(43) Pub. Date: Apr. 16, 2026

(54) SEMICONDUCTOR DEVICES USING COMPLEMENTARY FIELD EFFECT TRANSISTORS (CFETS)

(71) Applicant: Taiwan Semiconductor Manufacturing Company, Ltd., Hsinchu (TW)

(72) Inventors: Sheng-Po Huang, Hsinchu City (TW); Perng-Fei Yuh, Hsinchu City (TW)

(73) Assignee: Taiwan Semiconductor Manufacturing Company, Ltd., Hsinchu (TW)

(21) Appl. No.: 19/054,545

(22) Filed: Feb. 14, 2025

Related U.S. Application Data
(60) Provisional application No. 63/707,551, filed on Oct. 15, 2024.

(51) Int. Cl. H03F 3/45; G11C 7/06; H03K 5/24; H10D 62/13; H10D 84/85

(52) U.S. Cl. CPC H03F 3/4521; G11C 7/062; H03K 5/249; H10D 62/151; H10D 84/85

(57) ABSTRACT

Semiconductor devices using complementary field effect transistors are provided. A semiconductor device includes a first complementary field effect transistor (CFET) pair. The first CFET pair includes a first n-type transistor having a first gate electrode coupled with a first input of a differential pair. The first CFET pair includes a first p-type transistor having a second gate electrode coupled with the first input of the differential pair. The semiconductor device includes second CFET pair. The second CFET pair includes a second n-type transistor having a third gate electrode coupled with a second input of the differential pair. The second CFET pair includes a second p-type transistor having a fourth gate electrode coupled with the first input of the differential pair.

### CROSS-REFERENCE TO RELATED APPLICATION

This application claims priority to and the benefit of U.S. Provisional Application Number 63/707,551, filed Oct. 15, 2024, which is incorporated herein by reference in its entirety for all purposes.

### BACKGROUND

Semiconductor devices are used in a variety of electronic applications, such as personal computers, cell phones, digital cameras, and other electronic equipment. Semiconductor devices are fabricated by sequentially depositing insulating or dielectric layers, conductive layers, and semiconductor layers of material over a substrate, and patterning the various material layers using lithography to form circuit components and elements thereon. As the semiconductor industry has progressed into nanometer technology process nodes in pursuit of higher device density, improved performance, and lower costs, challenges from both fabrication and design issues have resulted in the development of three-dimensional circuit components.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of complementary field effect transistors (CFETs), in accordance with some embodiments.

FIG. 2 illustrates an example circuit implemented using a CFET, in accordance with some embodiments.

FIG. 3 illustrates a layout view of a circuit including a CFET, in accordance with some embodiments.

FIG. 4 illustrates another example circuit implemented using a CFET, in accordance with some embodiments.

FIG. 5 illustrates another layout view of a circuit including a CFET, in accordance with some embodiments.

FIG. 6 illustrates yet another example circuit implemented using a CFET, in accordance with some embodiments.

FIG. 7 illustrates yet another layout view of a circuit including a CFET, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Semiconductor devices can exhibit substantial variation between or across their respective portions. Components of these devices are sometimes provided physically larger than may be otherwise achievable, to reduce an effect of the variation of size (e.g., to account for lithographic or performant variance). Further, in some cases, the relative performance of a set (e.g., pair) of devices can itself constitute a design goal, such that decreased performance may be preferred to maintain a match with another device. For example, in the case of a comparator circuit, a reference value and a measured signal should be processed similarly, to reduce discrimination errors. Such matching is also useful in further circuits, including differential inputs. The matching of device-pairs may adopt heightened consideration when the devices are disposed at a pre-amplification stage of a circuit. For example, inputs of operational amplifiers (op-amps) can use physically large devices to aid in matching and other performance goals.

According to systems and methods of the present disclosure, semiconductor devices include various circuits using paired transistors, referred to as complementary field effect transistors (CFETs). In many cases, the complementary pair of a CFET can refer to complementary types of semiconductor materials, as in the case of a p-type transistor and n-type transistor of a paired set. However, as used herein, CFET sometimes refers to other complementary pairs, such as pair sharing of a same footprint, lateral surface of a semiconductor device, or circuit functionality. For example, a CFET may refer to first and second transistors of a transistor pair, wherein the respective transistors are laterally coextensive and vertically spaced from one another (e.g., stacked). For examples, one transistor of the transistor pair may be implemented as a front-side transistor and the other transistor of the transistor pair may be implemented as a back-side transistor. This vertical pairing can further reduce circuit size, since the stacked devices can exhibit increased density, relative to a single device layer. The transistor pairs can include paired sets of n-and p-type transistors, only p-type transistors, or only n-type transistors. Moreover, the CFETs may be employed in any of various circuits as may benefit from operational matching of transistor pairs, some examples of which are provided herein.

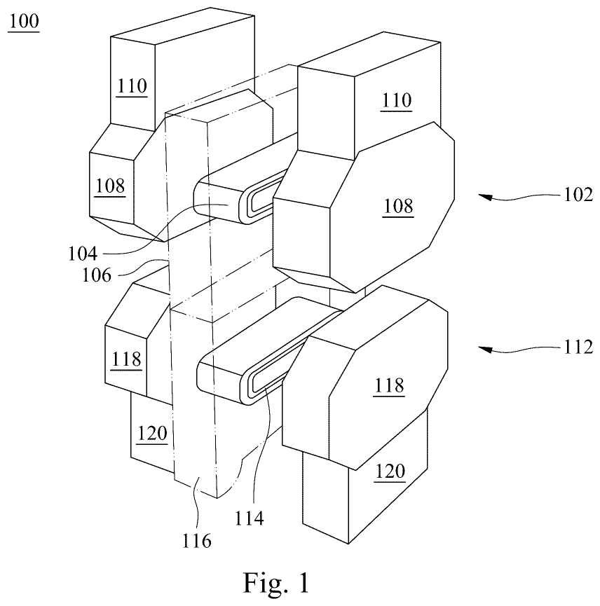

FIG. 1 illustrates a perspective view of a complementary field effect transistor (CFET) pair 100 in accordance with some embodiments. The depicted CFET 100 includes a first transistor 102 and second transistor 112, depicted as a front-side and a back-side transistor, respectively. The first transistor 102 and second transistor 112 can be referred to as vertically stacked with one-another. Referring particularly to the first transistor 102, a semiconductive channel 104 is coupled with a gate structure 106. The data structure may be coupled to a gate electrode coupled with a gate oxide in contact with the semiconductive channel 104. As is depicted, the semiconductive channel 104 can be surrounded by the gate structure 106, as in the case of a gate all around (GAA) implementation. However, such a depiction should not be construed as limiting. Various implementations of the present disclosure can include multi-channel GAA, finFET, and other implementations of the gate structure 106. The gate structure 106 couples with and terminates at source/drain structures 108 which are, in turn, coupled with further terminals such as an MD structure 110 configured to electrically couple with the source/drain structures 108 and metallization layers formed over the CFET 100.

A second transistor 112 of the CFET 100 likewise includes another semiconductive channel 114 coupled with another gate structure 116 including a gate electrode and gate oxide. The semiconductive channel 114 of the second transistor 112 couples with further source/drain structures 118. These source/drain structures 118 electrically couple with further MD structures 120 coupled with further metallization layers formed over the CFET 100. For example, the MD structure 110 of the first transistor 102 can couple to a front metallization layer formed over a front side of a semiconductor device including the CFET 100 and the MD structure 120 of the second transistor 112 can couple to a back metallization layer formed over a back side of the semiconductor device including the CFET 100.

Although depicted as abutting one another, the respective transistors 102, 112 may be spaced via an intermediate layer, such as a spacer or substrate. For example, the respective transistors 102, 112 may be formed on opposite sides of a substrate, or from stacked nanostructure layers. The respective transistors 102, 112 may be formed symmetrically across a lateral plane separating the transistors. Further, although the depicted CFET 100 may be formed in a substrate, such as a semiconductor wafer or inter-layer dielectric layer, such a substrate/layer is omitted to aid with the clarity of the depicted components.

The respective portions of the first transistor 102 and second transistor 112 may be congruent, mirrored, or otherwise disposed across a lateral plane therebetween. For example, a first gate structure 106 coupled with the first gate electrode can laterally overlap with, and be vertically spaced from, a second gate structure 106 of the second transistor 112. Further, first source/drain structures 108 coupled with the first gate structure may laterally overlap with and be vertically spaced from a second gate structures 106 of the second transistor 112.

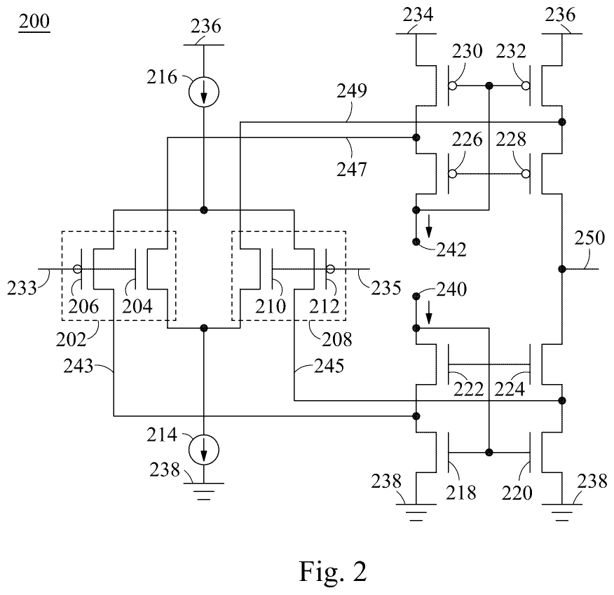

The semiconductive channels 104, 114 of the first transistor 102 and the second transistor 112 can include same or different material types. For example, one of the first transistor 102 or the second transistor 112 can include n-type material and the other of the first transistor 102 or the second transistor 112 can include p-type materials. In some embodiments, both of the paired transistors are p-type or n-type transistors. Likewise, a gate oxide or gate electrode of the first transistor 102 and the second transistor 112 can include the same or different materials. In some embodiments, the gate electrodes of like or unlike types of transistors can consist of or include a same material, such as where the respective gate structures 106, 116 are electrically connected to a same gate electrode, as is depicted in the circuit of FIG. 2.

FIG. 2 illustrates an example circuit 200 implemented using CFETs 100, in accordance with some embodiments. More particularly, the present circuit 200 is depicted as an operational amplifier (op-amp). The op-amp includes a differential input having a non-inverting input 233 and an inverting input 235. The combination of the non-inverting input 233 and the inverting input 235 may be referred to as a differential pair. The non-inverting input 233 is coupled with gates of an n-type transistor 204 and p-type transistor 206 of a first CFET 202. Accordingly, this non-inverting input 233 can receive voltage across an operating range (e.g., greater and less than a reference voltage, as is sometimes referred to as a ground). Similarly, an inverting input 235 is coupled with gates of an n-type transistor 210 and p-type transistor 212 of a second CFET 208. Accordingly, the non-inverting input 233 can also operate across the operating range.

The n-type transistors 204, 210 of the first CFET 202 and second CFET 208 can couple to a first current source 214, while the p-type transistors 206, 212 of the first CFET 202 and second CFET 208 can couple to a second current source 216. Accordingly, the transistors 204, 206, 210, 212 of each of the CFETs 202, 208 can exhibit a controlled (e.g., same) tail current so as to control a transconductance of the op-amp. Where the transistors of each CFET pair are formed over one another in accordance with according the present disclosure, the tail current provided through each transistor of the CFET pairs can exhibit congruency, such that process variations can corelate to one another, as may maintain symmetrical currents, increasing a signal to noise ratio of the op-amp, relative to other approaches. The first current source 214 can couple with a first supply voltage 238 (e.g., ground). The second current source 216 can couple with a second supply voltage 236 (e.g., VDD). The combination of the first CFET 202, the second CFET 208, and the current sources 214, 216 may be referred to as an input stage.

An output current generated by the input stage is amplified by an output stage of the op-amp. The present example depicts an output stage according to a cascode configuration including an NMOS stack coupled with drains of the p-type transistors 206, 212 of the input stage. More particularly, the p-type transistor 206 of the first CFET 202 couples with the NMOS stack via a first node 243 and the p-type transistor 212 of the second CFET 208 couples with the NMOS stack via a second node 245. The depicted example further depicts a PMOS stack coupled with drains of the n-type transistors 204, 210 of the input stage. More particularly, the n-type transistor 204 of the first CFET 202 couples with the PMOS stack via a third node 247 and the n-type transistor 210 of the second CFET 208 couples with the NMOS stack via a fourth node 249.

The NMOS stack includes a first transistor 218, second transistor 220, third transistor 222, and fourth transistor 224 (all n-type). The PMOS stack includes a first transistor 226, second transistor 228, third transistor 230, and fourth transistor 232 (all p-type). The NMOS stack is biased according to a first bias current 240 while the PMOS stack is biased according to a second bias current 242, though such currents may be provided according to a same bias, (e.g., may be equal or may vary according to process variation). An output 250 of the op-amp map be coupled with an output or load inductance, as driven by the cascode circuit of the output stage (e.g., one of the NMOS stack or the PMOS stack, based on a relative potential received at the non-inverting input 233 and the inverting input 235).

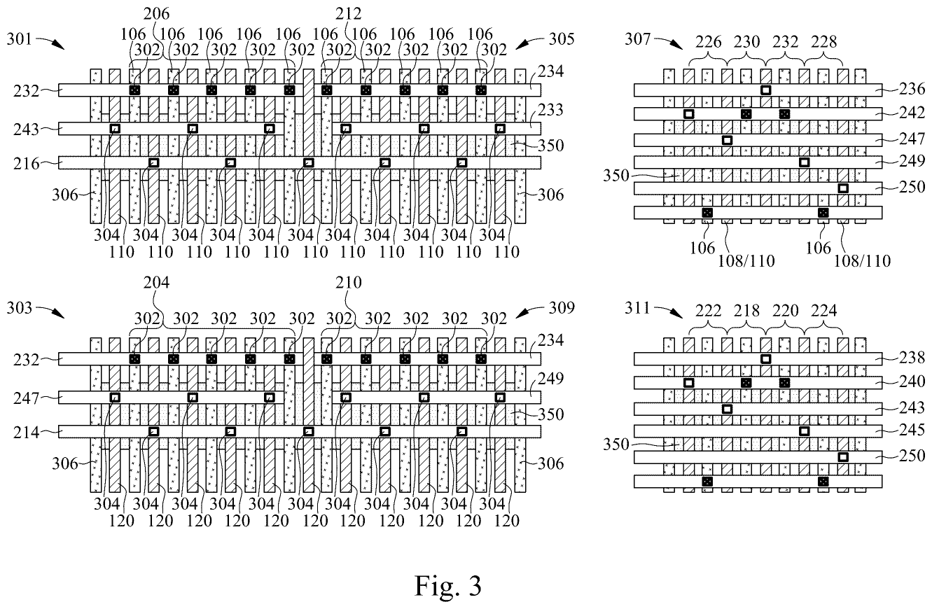

FIG. 3 illustrates a layout view of a circuit including a CFET, in accordance with some embodiments. For example, the circuit of FIG. 2 may be implemented according to the depicted layout. FIG. 3 includes views of a first surface 301 of a semiconductor device (e.g., a front surface) and a second surface 303 of the semiconductor device (e.g., a back surface). In some embodiments, further layers can be stacked. For example, multiple instances of the depicted layers may be stacked in a front-to-front, back-to-back, front-to back configuration, as may further increase lateral component density, relative to other approaches. The first surface 301 includes each of a first zone 305 and a second zone 307. The second surface 303 includes each of a third zone 309 and a fourth zone 311.

The first zone includes the first and second p-type transistors 206, 212. The second zone includes the PMOS stack. The third zone includes the first and second n-type transistors 204, 210. The fourth zone includes the NMOS stack. Each of the zones are laterally bounded by a Polysilicon on diffusion edge (PODE) boundary. The PODE is used to bound regions with multiple poly gates in semiconductor design to improve process control and yield. It aids in achieving consistent lithography and etching, such as by preventing damage to sensitive poly gates near diffusion edges and minimizing variability in electrical performance. The diffusion region (OD) is depicted as extending along each zone perpendicular to the gate structures 106, 116 and source/drain structures 108, 118. In some embodiments, such as an embodiment using a grown GAA channel, the region may refer to the channel itself. In some embodiments, the OD region 350 may refer to a fin region or planar region of a substrate. In some embodiments, the OD region 350 for the front-and back-side is a same OD region 350.

Referring to the first zone 305 of the first surface 301, the non-inverting input 233 is coupled with a logical gate structure at each of various gate vias 302 on the first surface 301 (e.g., a front surface). The first input of the differential pair and the second input of the differential pair can each couple with a same number of gate vias 302. Moreover, a first and second transistor of each CFET 202, 208 can couple with a same number of gate vias 302. Each of the depicted gate vias 302 corresponds to a separate physical gate structure 106, shown as disposed between source/drain structures 108 (e.g., MD structures 110). The gate structure 106 may be implemented according to various techniques, including a polysilicon (poly) gate, metal gate, or other gate structures. The second current source 216 and the first node 243 are connected to alternating ones of the source/drain structures 108 (e.g., using MD structures 110) of the p-type transistor 206 of the first CFET 202 (which implements the non-inverting input 233) by source/drain vias 304. The second current source 216 and second node 245 are connected to alternating ones of the source/drain structures 108 (e.g., using MD structures 110) of the p-type transistor 212 of the second CFET 208 (which implements the inverting input 235). The interconnects shown coupled with the gate vias 302 and source/drain vias 304 of the first surface can be implemented in at least one metallization layer over the first surface 301 of the semiconductor device. For example, the vertical interconnects can be formed in at least a first front-metallization layer (FM0), and can include portions of further layers (e.g., FM1, FM2, and so forth).

Referring to the second zone 307 of the first surface 301, the PMOS stack is shown coupled with the third node 247, the fourth node 249, and the bias current 242 as depicted in FIG. 2. Connections to the second supply voltage 236 and output 250 are also depicted. More particularly, the first transistor 226 and second transistor 228 of the PMOS stack are coupled to each other via a metallization layer interconnect. Gate vias 302 are shown coupling the third transistor 230 and fourth transistor 232 of the PMOS stack with a node for a bias current 242. Source/drain vias 304 couple the PMOS stack with other portions of a circuit as depicted in FIG. 2, including the output 250.

Referring now to the second surface 303, a third zone 309 includes n-type devices of the CFETs 202, 208. The n-type transistors 204, 210 implementing the non-inverting input 233 and inverting input 235 are coupled with a logical gate structure at each of various gate vias 302 on the second surface 303 (e.g., a back surface). Each of the depicted gate vias 302 corresponds to a separate physical gate structure 116, shown as disposed between source/drain structures 118 (e.g., using MD structures 120). As for the first surface 301, these gate structures 116 can be implemented according to various techniques. The first current source 214 and third node 247 are connected to alternating ones of the source/drain structures 118 (e.g., using MD structures 120) of the n-type transistor 204 of the first CFET 202. The first current source 214 and fourth node 249 are connected to alternating ones of the source/drain structures 118 (e.g., using MD structures 120) of the n-type transistor 210 of the second CFET 208 (as implements the inverting input 235).

Referring now to a fourth zone of the second surface 303, the NMOS stack is depicted as coupled to the first node 243 and second node 245 as well as a node for the bias current 240 as depicted in FIG. 2. The connections to the first supply voltage 238 and output 250 are also depicted. Gate vias 302 are shown coupling the first transistor 218 and second transistor 220 of the NMOS stack with the bias current 240. The third transistor 222 and fourth transistor 224 of the NMOS stack are coupled to each other via a metallization layer. Source/drain vias 304 couple the NMOS stack with other portions of a circuit as depicted in FIG. 2, including the output 250. Accordingly, the output 250 may be driven by either of the PMOS stack or the NMOS stack.

Each transistor formed on the first surface is depicted as a p-type transistor and each transistor formed on the second surface is an n-type transistor. Such an implementation may reduce a number of operations for fabricating some of the semiconductor devices described herein. For example, additive or subtractive processes used to manufacture a semiconductor device can vary between device types. Accordingly, a process performed to form a p-type device on a first surface 301 can be omitted from a formation of a second surface 303. Similarly, a process performed to form n-type devices on the second surface 303 can be omitted when forming p-type devices on the first surface 301 (e.g., an opposite surface from the second surface 303). Such an implementation can be used in the generation of various circuits in addition to those explicitly provided herein. Further, in some embodiments, circuits can include zones of n-type or p-type devices (e.g., transistors), such as at lateral zones along a same surface of the devices. For example, the depicted PMOS stack can be laterally or vertically spaced from the first p-type transistor 206 and second p-type transistor 212, in some embodiments.

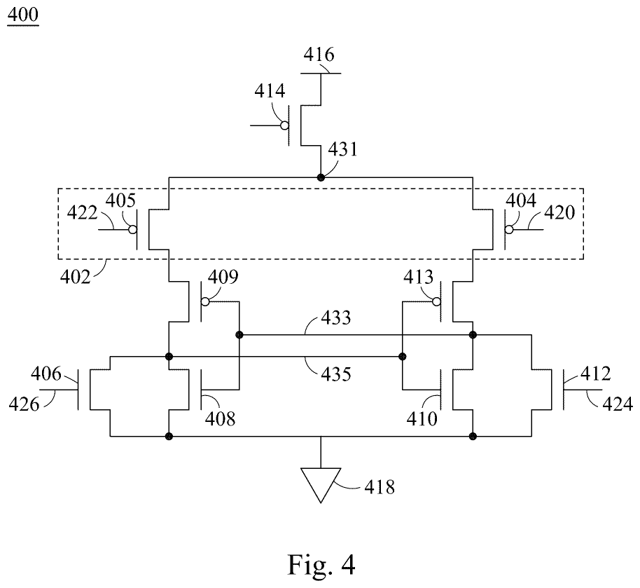

FIG. 4 illustrates another example circuit 400 implemented using a CFET 402, in accordance with some embodiments. The circuit 400 may operate as a sense amplifier or dynamic comparator, as may implement a flash analog to digital circuit (ADC), successive approximation register, or other comparators. The circuit is configured to process a measured signal received at a first input 420 and a reference signal as received at a second input 422. The first input 420 is a gate of a first p-type transistor 404 and the second input 422 is a gate of a second p-type transistor 405. The first input 420 and second input 422 may be referred to as an input pair. The first and second p-type transistors 404, 405 can be implemented as transistors of a CFET pair 402, as may exhibit correlated process variations to reduce discrimination error between the reference signal and measured signal. The CFET 402 may be referred to as a differential input stage, as is configured to receive the measured and reference value. The cross coupled inverters may be referred to as a clock-gated positive feedback stage.

Reset inputs, as may be configured to receive a clock or other strobe signal, are depicted at a third transistor 406, fourth transistor 408, and fifth transistor 409 implementing a first half of a cross coupled pair, along with a sixth transistor 410, seventh transistor 412, and eighth transistor 413. The cross coupled pair is sometimes referred to as a regenerative latch for its latching of a value until reset or resampled. A pre-charge transistor 414 is coupled with a supply voltage 416 to pre-charge a first node 431 of the comparator circuit. For example, the supply voltage 416 can be VDD as referenced to a second supply voltage 418 (e.g., ground). Actuation of clock or strobe inputs 424, 426 can clear a state of a second node 433 and a third node 435 of the cross-coupled pair.

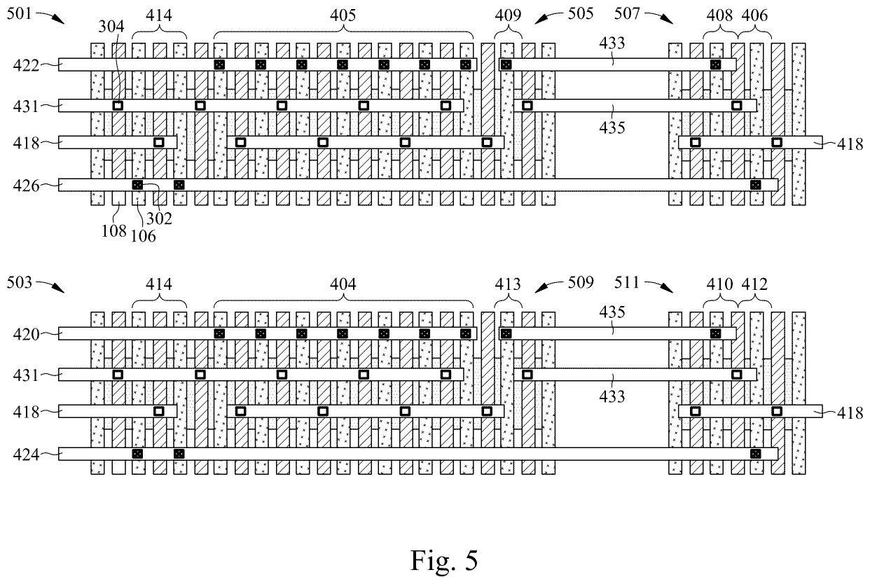

FIG. 5 illustrates another layout view of a semiconductor device implementing the circuit 400 including the CFET 402 of FIG. 4, in accordance with some embodiments. The CFET 402 includes a second p-type transistor 405 on a first surface 501 of a semiconductor device and a first p-type transistor 404 on a second surface 503 of the semiconductor device. As described above, the first p-type transistor 404 and second p-type transistor 405 may be formed as generally symmetrically across a lateral plane so as to reduce discrimination error between a reference and measurement signal, as well as to increase a lateral density of a device. For example, the first p-type transistor 404 and second p-type transistor 405 can be mirrored images of one-another (e.g., any of a gate electrode, gate oxide, semiconductive channel 104, or other component can be a same dimension and include or consist of same materials).

A first zone 505 of the semiconductor device is located along the first surface 501 and includes the second p-type transistor 405, a pre-charge transistor 414 portion, and the fifth transistor 409. A second zone 507 includes the third transistor 406 and fourth transistors 408 of the same half of the cross coupled pair as the fifth transistor 409. A third zone 509 of the semiconductor device is located along the second surface 503 and includes the first p-type transistor 404, a pre-charge transistor 414 portion, and the eighth transistor 413. A fourth zone 511 includes the sixth transistor 410 and seventh transistors 412 of the same half of the cross coupled pair as the eighth transistor 413.

Referring to the first zone 505, the second input 422 (e.g., an input for a reference signal) is depicted as a logical gate structure at each of various gate vias 302 on the first surface 501 (e.g., a front surface). Each of the depicted gate vias 302 corresponds to a separate physical gate structure 106 of the second p-type transistor 405, shown as disposed between source/drain structures 108 (e.g., MD structures 110). Source/drain structures 108 are sometimes referred to as source/drain regions, without limiting effect. The pre-charge transistor 414 is connected to proximal separate physical gate structures 106. The gates are, in turn, disposed between and coupled with source/drain structures 108 (e.g., MD structures 110) for clock/strobe inputs 424, 426 (depicted as bridged) and the first node 431. The fifth transistor 409 is also shown as adjacent, having a source/drain coupled with a source/drain of the second p-type transistor 405. Another of the source/drain of the fifth transistor 409 is coupled with the third node 435 and the gate of the fifth transistor 409 is coupled with the fourth transistor 408 (the second node 433) of the second zone 507.

With continued reference to the second zone 507, The fourth transistor 408 shares a source/drain with the third transistor 406 (the third node 435). A different source/drain of the fourth transistor 408 is coupled with a second supply voltage 418 using the metallization layer. The metallization layer also couples the second supply voltage 418 with the third transistor 406.

While each of the second p-type transistor 405, the pre-charge transistor 414, and the fifth transistor 409 are provided as p-type transistors, the third transistor 406 and fourth transistor 408 are provided as n-type transistors. The n-type transistors are depicted as spaced from the p-type transistors. Such spacing can correspond to lateral spacing or vertical spacing. For example, at least the second node 433 and third node 435 can include a TSV or other conductive structure traversing from a first surface 501 of the semiconductive device to another surface. Accordingly, n-type devices can be co-located on a same surface to simplify manufacturing as described above with regard to FIG. 4. For example, the n-type devices can be stacked in a third or fourth surface. Likewise, in some embodiment, the p-type devices can be collocated on a same surface (or other zone).

Referring to a third zone 509, the first input 420 (e.g., an input for a measurement signal) is depicted as a logical gate structure at each of various gate vias 302 on the second surface 503 (e.g., a back surface). Each of the depicted gate vias 302 corresponds to a separate physical gate structure 106 of the first p-type transistor 404, shown as disposed between source/drain structures 118 (e.g., using MD structures 120). The pre-charge transistor 414 portion is connected to proximal separate physical gate structures 116 (depicted as a single logical gate structure in the schematic of FIG. 4). The gates are, in turn, disposed between and coupled with source/drain structures 118 (e.g., MD structures 120) for the first node 431 and the strobe inputs 424, 426 (as may be clock-driven to execute comparisons at regular interval. The eighth transistor 413 is also shown as adjacent, having a source/drain coupled with a source/drain of the first p-type transistor 404. Another of the source/drain of the eighth transistor 413 is coupled with the second node 433 and the gate of the eighth transistor 413 is coupled with the sixth transistor 410 (the third node 435) of the fourth zone 511.

With continued reference to the fourth zone 511, the sixth transistor 410 shares a source/drain with the seventh transistor 412 (the second node 433). A different source/drain of the sixth transistor 410 is coupled with a second supply voltage 418 using the metallization layer. The metallization layer also couples the second supply voltage 418 with the seventh transistor 412. While each of the first p-type transistor 404, the pre-charge transistor 414, and the eighth transistor 413 are provided as p-type transistors, the sixth transistor 410 and seventh transistor 412 are provided as n-type transistors. As described above, the p-type or n-type transistors may be co-located on a same zone or surface of the semiconductor device. Further depicted are PODE regions as may define a boundary for the depicted OD regions or zones as described above with regard to the OD regions 350 of FIG. 3.

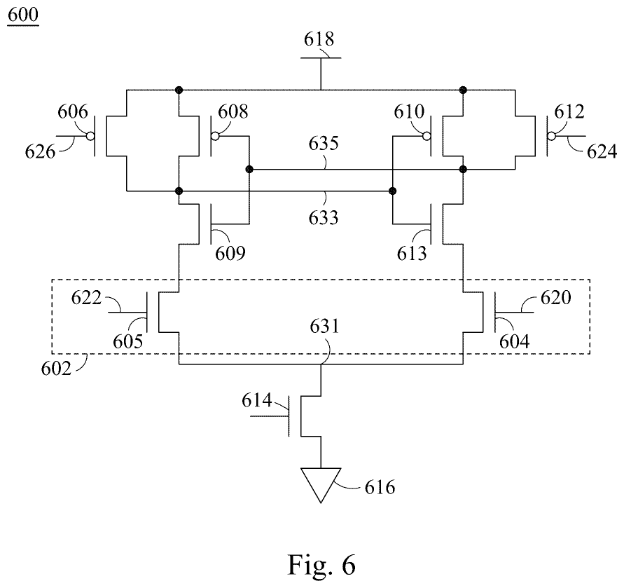

FIG. 6 illustrates yet another example circuit 600 implemented using a CFET 602, in accordance with some embodiments. As in FIG. 4, the circuit 600 can implement a sense amplifier or dynamic comparator, though the presently depicted figure is shown as having different topology. A first input 620 receives a measured signal and a second input 622 receives a reference signal. The first input 620 is a gate of a first n-type transistor 604 and the second input 622 is a gate of a second n-type transistor 605. The first and second n-type transistors 604, 605 can be implemented as transistors of a CFET pair 602, as may exhibit correlated process variations. Accordingly, whereas the CFET pair 402 of FIG. 4 includes a pair of p-type transistors, a CFET 602 of the present circuit includes a pair of n-type transistors. The CFET 402 may be referred to as a differential input stage, as is configured to receive the measured and reference value. The cross coupled inverters may be referred to as a strobe-gated positive feedback stage (e.g., clock-gated).

A reset transistor 614 couples to the first input 620 and second input 622 at a first node 631 to reset a state of the circuit 600 and a regenerative latch. The regenerative latch includes cross coupled transistors 606, 608, 609, 610, 612, 613 to store a value via a cross coupled second node 633 and third node 635. The reset transistor 614 couples the first node 631 to a supply voltage 616. Further pre-charge inputs 624, 626 couple another supply voltage 618 to the second node 633 and third node 635. Upon receipt of a clock edge or other strobe, the circuit will store a digital value based on whichever of the first input 620 or the second input 622 is higher. In this way, the circuit can store an indication of whichever of the inputs is greater, as may be cascaded to form an ADC or can be used in other comparator applications. The construction of the CFET can aid to reduce discrimination error between reference and measurement signals. For example, as described above, the respective transistors of the CFET can be formed with similar (e.g., mirrored) geometry and similar (e.g., same) materials. Such symmetry can include geometry of various structures of a transistor, as well as connections therebetween, such as a number of gate vias, source/drain vias, a dimension of metallization layer connections, or other aspects of the transistor. Such an implementation may further increase lateral density so as to reduce capacitive or resistive losses due to signal routing, and thus may further improve accuracy of comparisons.

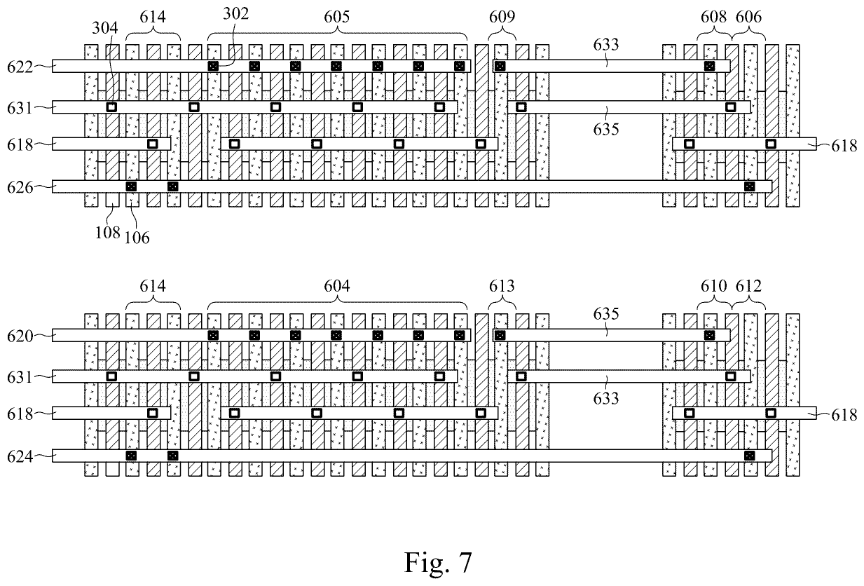

FIG. 7 illustrates yet another layout view of a circuit including a CFET, in accordance with some embodiments. The present layout substitutes the n-type transistors of the circuit of FIG. 4 for p-type transistors and the p-type transistors of the circuit of FIG. 4 for n-type transistors. Further, the supply voltages 616, 618 may be inverted relative to the supply voltages 416, 418 of FIG. 4. For example, the reset transistor 614 may, upon actuation, pull the circuit to ground rather than another VDD referenced to ground, as in the case of the pre-charge transistor 414 of FIG. 4. The present layout is otherwise depicted similarly to the layout of FIG. 5, and thus relevant description is not repeated to avoid redundancy of the present disclosure.

In one aspect of the present disclosure, a semiconductor device is provided. The semiconductor device includes a first complementary field effect transistor (CFET) pair. The first CFET pair includes a first n-type transistor having a first gate electrode coupled with a first input of a differential pair. The first CFET pair includes a first p-type transistor vertically stacked with the first n-type transistor and having a second gate electrode coupled with the first input of the differential pair. The semiconductor device includes second CFET pair. The second CFET pair includes a second n-type transistor having a third gate electrode coupled with a second input of the differential pair. The second CFET pair includes a second p-type transistor vertically stacked with the second n-type transistor and having a fourth gate electrode coupled with the first input of the differential pair.

In another aspect of the present disclosure a complementary field effect transistor (CFET) pair includes a first transistor having a first gate electrode coupled with a first input of an input pair. The CFET pair includes a second transistor having a same type as the first transistor and a second gate electrode coupled with a second input of the input pair. The semiconductor device is configured to compare a first voltage received at the first input of the input pair to a second voltage received at the second input of the input pair.

In another aspect of the present disclosure a complementary field effect transistor (CFET) pair includes a complementary field effect transistor (CFET) pair. The CFET pair includes a first transistor having a first gate electrode coupled with a first input of an input pair. The CFET pair includes a second transistor vertically stacked with the first transistor and a second gate electrode coupled with a second input of the input pair. The differential input circuit is configured to compare a first voltage received at the first input of the input pair to a second voltage received at the second input of the input pair, and convey the comparison a strobe-gated positive feedback stage.

As used herein, the terms “about” and “approximately” generally indicates that the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first complementary field effect transistor (CFET) pair comprising:
a first n-type transistor having a first gate electrode coupled with a first input of a differential pair; and
a first p-type transistor vertically stacked with the first n-type transistor and having a second gate electrode coupled with the first input of the differential pair; and
a second CFET pair comprising:
a second n-type transistor having a third gate electrode coupled with a second input of the differential pair; and
a second p-type transistor vertically stacked with the second n-type transistor and having a fourth gate electrode coupled with the second input of the differential pair.

2. The semiconductor device of claim 1, wherein the first n-type transistor comprises:
a first gate structure coupled with the first gate electrode, laterally overlapping with and vertically spaced from a second gate structure of the first p-type transistor; and
first source/drain regions coupled with the first gate structure, laterally overlapping with and vertically spaced from, second gate structures of the first p-type transistor.

3. The semiconductor device of claim 1, wherein the first n-type transistor and the first p-type transistor are formed symmetrically across a lateral plane separating the first n-type transistor and the first p-type transistor.

4. The semiconductor device of claim 1, wherein the first n-type transistor and the first p-type transistor are each coupled with a same OD region.

5. The semiconductor device of claim 1, wherein the first input of the differential pair and the second input of the differential pair are each coupled with a same OD region.

6. The semiconductor device of claim 1, wherein the first n-type transistor and the first p-type transistor comprise a same number of gate vias coupling with a metallization layer formed over the semiconductor device.

7. The semiconductor device of claim 6, wherein the metallization layer comprises:
a front-side metallization layer coupled with gate vias of one of the first n-type transistor or the first p-type transistor; and
a back-side metallization layer coupled with gate vias of the other of the first n-type transistor or the first p-type transistor.

8. The semiconductor device of claim 1, wherein the differential pair is a differential input for an operational amplifier (op-amp), the op-amp comprising:
a first plurality of transistors on a first side of the semiconductor device, the first plurality of transistors comprising the first n-type transistor; and
a second plurality of transistors on a second side of the semiconductor device, the second plurality of transistors comprising the first p-type transistor.

9. The semiconductor device of claim 8, wherein:
the op-amp is supplied by a first supply voltage and a second supply voltage, the first supply voltage greater than the second supply voltage;
the first p-type transistor is configured to receive voltages lower than the second supply voltage; and
the first n-type transistor is configured to receive voltages greater than the second supply voltage.

10. A semiconductor device comprising:
a first complementary field effect transistor (CFET) pair comprising:
a first transistor having a first gate electrode coupled with a first input of an input pair; and
a second transistor vertically stacked with the first transistor and having a same type as the first transistor and a second gate electrode coupled with a second input of the input pair,
wherein the semiconductor device is configured to compare a first voltage received at the first input of the input pair to a second voltage received at the second input of the input pair.

11. The semiconductor device of claim 10, wherein the first transistor is vertically spaced from and laterally overlapping with the second transistor.

12. The semiconductor device of claim 10, wherein the first transistor and the second transistor are n-type transistors of a differential input stage of a dynamic comparator or a sense amplifier, the n-type transistors being coupled with a clock-gated positive feedback stage.

13. The semiconductor device of claim 10, wherein the first transistor and the second transistor are formed symmetrically across a lateral plane separating the first transistor from a second p-type transistor.

14. The semiconductor device of claim 10, wherein the first transistor and the second transistor comprise a same number of gate vias coupling with a metallization layer formed over the semiconductor device, the metallization layer comprising:
a front-side metallization layer coupled with gate vias of the first transistor; and
a back-side metallization layer coupled with gate vias of the second transistor.

15. The semiconductor device of claim 10, wherein the first transistor and the second transistor are coupled with a same OD region.

16. A semiconductor device comprising:
differential input circuit comprising:
a first complementary field effect transistor (CFET) pair comprising:
a first transistor having a first gate electrode coupled with a first input of an input pair; and
a second transistor vertically stacked with the first transistor and a second gate electrode coupled with a second input of the input pair,
wherein the differential input circuit is configured to compare a first voltage received at the first input of the input pair to a second voltage received at the second input of the input pair, and convey the comparison a strobe-gated positive feedback stage.

17. The semiconductor device of claim 16, wherein:
the differential input circuit is an input for one of a dynamic comparator or a sense amplifier; and
a strobe of the strobe-gated positive feedback stage is a clock.

18. The semiconductor device of claim 16, wherein the first transistor and the second transistor are of a same type.

19. The semiconductor device of claim 16, wherein the first transistor and the second transistor are formed symmetrically across a lateral plane separating the first transistor from a second p-type transistor.

20. The semiconductor device of claim 16, wherein the first transistor and the second transistor comprise a same number of gate vias coupling with a metallization layer formed over the semiconductor device, the metallization layer comprising:
a front-side metallization layer coupled with gate vias of the first transistor; and
a back-side metallization layer coupled with gate vias of the second transistor.
